(19) United States
(12) Patent Application Publication
(10) Pub. No.: US 2012/0181570 A1
(43) Pub. Date: Jul. 19, 2012

(54) SEMICONDUCTOR LIGHT EMITTING DEVICE AND FABRICATION METHOD THEREOF

(75) Inventors: Hyung Duk KO, Seoul (KR); Yung Ho RYU, Suwon (KR); Tae Sung JANG, Hwaseong (KR)

(73) Assignee: SAMSUNG LED CO., LTD., Yongin-City (KR)

(21) Appl. No.: 13/347,094

(22) Filed: Jan. 10, 2012

(30) Foreign Application Priority Data
Jan. 14, 2011 (KR) 10-2011-0004163

(51) Int. Cl. H01L 33/36; H01L 33/52

(52) U.S. Cl. 257/99; 438/26; 257/E33.062; 257/E33.059

(57) ABSTRACT

A semiconductor light emitting device and a fabrication method thereof are provided. The semiconductor light emitting device includes: a light-transmissive substrate including opposed first and second main planes and having prominences and depressions formed on at least one of the first and second main planes thereof; a light emitting structure formed on the first main plane of the substrate and including a first conductive semiconductor layer, an active layer, and a second conductive layer; a first electrode structure connected to the first conductive semiconductor layer; a second electrode structure connected to the second conductive semiconductor layer.

### CROSS-REFERENCE TO RELATED APPLICATIONS

This application claims the priority of Korean Patent Application No. 10-2011-0004163 filed on Jan. 14, 2011, in the Korean Intellectual Property Office, the disclosure of which is incorporated herein by reference.

### BACKGROUND OF THE INVENTION

1. Field of the Invention

The present invention relates to a semiconductor light emitting device and a fabrication method thereof.

2. Description of the Related Art

In general, a luminous element is an element used to transmit a signal obtained by converting electrical energy into light in the form of infrared rays or visible light, by using the characteristics of a compound semiconductor. The LED is a type of electroluminescence (EL) element, and currently, an LED using a group III-V compound semiconductor has been put to practical use (or has been commercialized). A group III nitride-based compound semiconductor is generally formed on a substrate made of sapphire (Al₂O₃), and in order to enhance luminous efficiency, namely, light extraction efficiency, research into LEDs having various structures has been conducted, and currently, research aimed at enhancing light extraction efficiency by forming a prominence and depression structure on a light extraction region of a light emitting element is ongoing.

The passage of light is limited to the interface of material layers because the material layers have different indices of refraction. In the case of a smooth interface, when light moves from a semiconductor layer having a large index of refraction toward an air layer (n=1) having a small index of refraction, the light must be made incident to the smooth interface at a predetermined angle or less, with respect to a normal direction of the interface. If light is made incident at the predetermined angle or greater, light may be totally internally reflected from the smooth interface, significantly reducing light extraction efficiency. Thus, in order to solve this problem, a method of introducing a prominence and depression structure to the interface has been introduced.

Also, when a GaN-based compound semiconductor layer is formed on a sapphire substrate, a defect may be generated due to lattice mismatching and may even spread to the interior of an active layer, and such an internal crystal defect of a semiconductor device degrades light extraction efficiency.

### SUMMARY OF THE INVENTION

An aspect of the present invention provides a high quality nitride semiconductor light emitting device having reduced dislocation defects.

Another aspect of the present invention provides a semiconductor light emitting device having external light extraction efficiency enhanced by a prominence and depression structure.

Another aspect of the present invention provides a semiconductor light emitting device having an electrode structure simplified to increase a light emission area emitting light uniformly.

Another aspect of the present invention provides a method for fabricating a semiconductor light emitting device capable of enhancing process efficiency and reducing a defect rate.

According to an aspect of the present invention, there is provided a semiconductor light emitting device including: a light-transmissive substrate including opposed first and second main planes and having prominences and depressions formed on at least one of the first and second main planes thereof; a light emitting structure formed on the first main plane of the substrate and including a first conductive semiconductor layer, an active layer, and a second conductive layer sequentially formed in a direction away from the first main plane; a first electrode structure disposed at a side of the substrate opposed to the light emitting structure and including a conductive via connected to the first conductive semiconductor layer through the second conductive semiconductor layer and the active layer; a second electrode structure disposed on the side of the substrate opposed to the light emitting structure and connected to the second conductive semiconductor layer; and an insulator electrically separating the first electrode structure from the second conductive semiconductor layer, the active layer, and the second electrode structure.

A plurality of conductive vias may be provided, and the insulator may be formed to fill the regions between the plurality of conductive vias and the light emitting structure.

The first and second electrode structures may be formed to face the same direction.

The semiconductor light emitting device may further include a first electrode pad connected to the conductive vias.

The semiconductor light emitting device may further include a second electrode pad formed on an upper surface of the second conductive semiconductor layer.

The light-transmissive substrate may be an insulating substrate.

The prominences and depressions formed on the light-transmissive substrate may include a convex portion with a sloped lateral face.

The first and second conductive semiconductor layers may be n-type and p-type semiconductor layers, respectively.

According to another aspect of the present invention, there is provided a method for fabricating a semiconductor light emitting device, including: preparing a light-transmissive substrate including opposed first and second main planes and having prominences and depressions formed on at least one of the first and second main planes; forming a light emitting structure in which a first conductive semiconductor layer, an active layer, and a second conductive semiconductor layer are sequentially stacked on a prominence and depression surface of the substrate; etching portions of the second conductive semiconductor layer and the active layer to expose at least a portion of the first conductive semiconductor layer; forming a first electrode structure including conductive vias electrically connected to the first conductive semiconductor layer on the etched region; forming a second electrode structure electrically connected to the second conductive semiconductor layer on the second conductive semiconductor layer; and forming an insulator to electrically separate the first electrode structure from the second conductive semiconductor layer, the active layer, and the second electrode structure.

The conductive vias may be formed to penetrate the second conductive semiconductor layer and the active layer.

In the forming of the insulator, the insulator may be formed to fill the etched regions formed between the conductive vias and the light emitting structure.

The prominences and depressions formed on at least one of the first and second main planes may include a convex portion with a sloped lateral face, and at least a portion of the first conductive semiconductor layer may be grown from the lateral face of the convex portion.

The method may further include: forming an insulator to cover the surface of the light emitting structure, before forming the conductive vias.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view schematically showing a semiconductor light emitting device according to an embodiment of the present invention;

FIG. 2 is a schematic cross-sectional view of the semiconductor light emitting device taken along line A-A′ in FIG. 1;

FIG. 3 is a schematic top view of the semiconductor light emitting device of FIG. 1;

FIGS. 4 through 10 are views sequentially showing a method for fabricating a semiconductor light emitting device according to an embodiment of the present invention; and

FIG. 11 is a view schematically showing a mounting form of a semiconductor light emitting device package according to an embodiment of the present invention.

### DETAILED DESCRIPTION OF THE PREFERRED EMBODIMENT

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

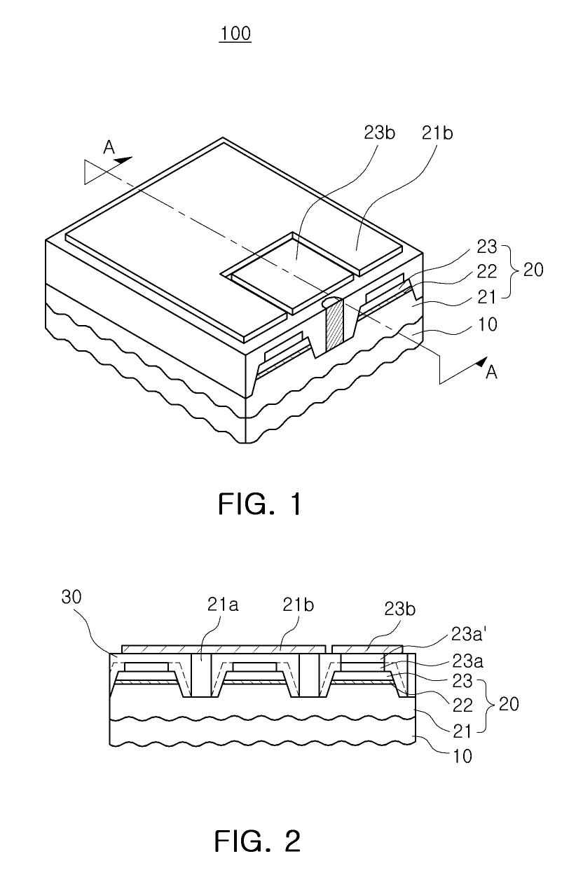

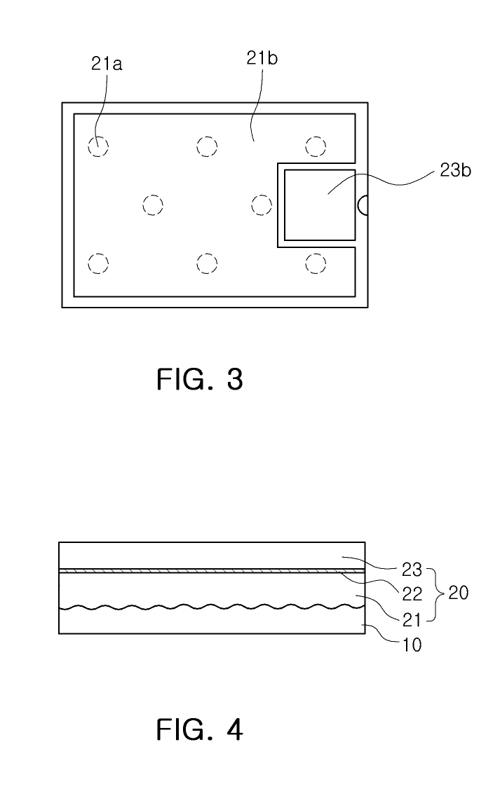

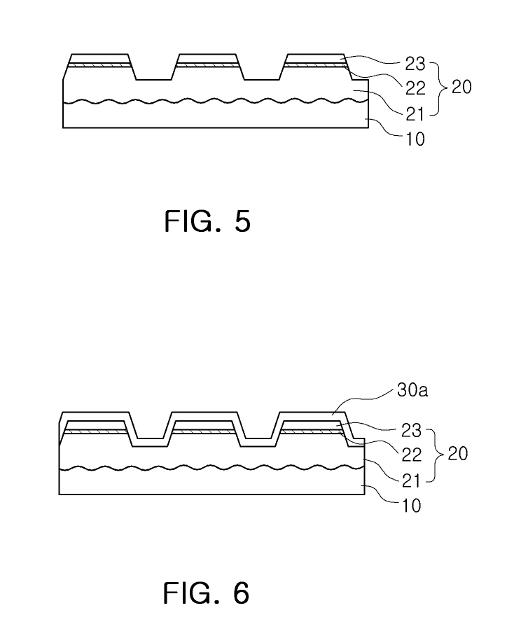

FIG. 1 is a perspective view schematically showing a semiconductor light emitting device according to an embodiment of the present invention. FIG. 2 is a schematic cross-sectional view of the semiconductor light emitting device taken along line A-A′ in FIG. 1. FIG. 3 is a schematic top view of the semiconductor light emitting device of FIG. 1. With reference to FIGS. 1 through 3, a semiconductor light emitting device 100 according to the present embodiment will be described below.

With reference to FIGS. 1 through 3, a semiconductor light emitting device 100 according to the present embodiment includes a light-transmissive substrate 10 including opposed first and second main planes and having prominences and depressions formed on at least one of the first and second main planes thereof, a light emitting structure 20 formed on the first main plane of the light-transmissive substrate 10 and including a first conductive semiconductor layer 21, an active layer 22, and a second conductive layer 23 sequentially formed in a direction away from the first main plane, a first electrode structure 21A disposed at the opposite side of the substrate 10, based on the light emitting structure 20 and including a conductive via 21a connected to the first conductive semiconductor layer 21 through the second conductive semiconductor layer 23 and the active layer 22, a second electrode structure 23A including a second electrode layer 23a connected to the second conductive semiconductor layer 23, and an insulator 30 electrically separating the first electrode structure 21A from the second conductive semiconductor layer 23, the active layer 22, and the second electrode structure 23A.

In the present embodiment, the first and second conductive semiconductor layers 21 and 23 may be n type and p type semiconductor layers and may be formed of nitride semiconductors, respectively. Thus, in the present embodiment, the first and second conductive semiconductor layers may be understood to denote n type and p type semiconductor layers, respectively, but the present invention is not limited thereto. The first and second conductive semiconductor layers 21 and 23 may have an empirical formula AlₓIn_{y}Ga_{(1-x-y)}N (Here, 0≦x≦1, 0≦y≦1, 0≦x+y≦1), and made be made of, for example, a material such as GaN, AlGaN, InGaN, or the like. The active layer 22 formed between the first and second conductive semiconductor layers 21 and 23 may emit light having a certain amount of energy, according to the recombination of electrons and holes, and may have a multi-quantum wall (MQW) structure, e.g., an InGaN/GaN structure, in which quantum wall layers and quantum barrier layers are alternately stacked. Meanwhile, the first and second conductive semiconductor layers 21 and 23 and the active layer 22 may be formed by using a semiconductor layer growth process known in the art, such as MOCVD, MBE, HVPE, and the like.

The light-transmissive substrate 10 may be made of a material such as sapphire, SiC, MgAl₂O₄, MgO, LiAlO₂, LiGaO₂, GaN, or the like. In this case, sapphire, a crystal having Hexa-Rhombo R3c symmetry, has lattice constants of 13,001 Å and 4.758 Å, respectively, in c-axis and a-axis directions and has C(0001), A(1120), and R(1102) planes, etc. In this case, the C plane allows a nitride thin film to be relatively easily grown therefrom and is stable at high temperatures, so it is largely used as a growth substrate.

A prominence and depression structure may be formed on the first and second main planes of the light-transmissive substrate 10, and the light emitting structure 20 including the first conductive semiconductor layer 21, the active layer 22, and the second conductive semiconductor layer 23 may be formed on a surface of the light-transmissive substrate 10 having the prominence and depression structure formed thereon. The prominence and depression structure may be formed by etching a portion of the light-transmissive substrate 10, so in this case, the prominence and depression structure may be made of the same material as that of the light-transmissive substrate. The prominence and depression structure may also be made of a material different to that of the light-transmissive substrate 10. In an embodiment of the present invention, since the prominence and depression structure is formed on the interface between the light-transmissive substrate 10 and the first conductive semiconductor layer 21, light emitted from the active layer 22 of the light emitting structure 20 may have various paths, reducing a rate of light absorbed in the semiconductor layer and increasing a light diffusion rate, thus enhancing external light extraction efficiency.

In detail, the prominence and depression structure may be formed by etching a portion of the light-transmissive substrate 10 for a semiconductor growth, so as to have a regular or irregular shape, and alternatively, the prominence and depression structure may be made of a heterogeneous material having a different refractive index from that of the light-transmissive substrate 10, whereby a light proceeding change effect can be maximized by the difference in the refractive indices of the different materials used to form the light transmissive substrate 10, the first conductive semiconductor layer 21, and the prominence and depression structure. As the heterogeneous material used to form the prominence and depression structure, a transparent conductive material or a transparent insulating material may be used. As the transparent insulating material, a material such as SiO₂, SiNₓ, Al₂O₃, HfO, TiO₂, or ZrO may be used, and as the transparent conductive material, a transparent conductive oxide (TCOs) such as ZnO or In oxide containing an additive (Mg, Ag, Zn, Sc, Hf, Zr, Te, Se, Ta, W, Nb, Cu, Si, Ni, Co, Mo, or Cr) may be used, but the present invention is not limited thereto.

The prominence and depression structure formed on an upper surface of the light-transmissive substrate 10, on which the light emitting structure 20 is grown, can lessen stress due to a difference in a lattice constant at the interface between the light-transmissive substrate 10 and the first conductive semiconductor layer 21. For example, when the group III nitride-based first conductive semiconductor layer 21 is grown on the sapphire substrate, i.e., a nitride semiconductor growth substrate, a dislocation defect occurs due to a difference between the lattice constants of the substrate and the group III nitride-based compound semiconductor layer, and the generated dislocation defect propagates upwardly to degrade crystal quality in the first conductive semiconductor layer 21. In the present embodiment, the prominence and depression structure is configured to have a convex portion with a sloped lateral face on the light-transmissive substrate 10, whereby the first conductive semiconductor layer 21 is grown from the side of the convex portion, thus preventing the dislocation defect from propagating upwardly. Thus, a high quality nitride semiconductor light emitting device can be provided, and accordingly, an effect of increasing the internal quantum efficiency can be obtained.

In the present embodiment, within the light emitting structure 20, the first electrode structure 21A including the conductive via 21a connected to the first conductive semiconductor layer 21 through the second conductive semiconductor layer 23 and the active layer 22 and the second electrode structure 23A connected to the second conductive semiconductor layer 23 may be formed. The first and second electrode structures 21A and 23A serve to allow the first and second conductive semiconductor layers 21 and 23 to be externally electrically connected, respectively. The first and second electrode structures 21A and 23A may include first and second electrode pads 21b and 23b, respectively. The number, shape, and pitch of conductive vias 21a, contact regions of the conductive vias 21a with the first and second conductive semiconductor layers 21 and 23, and the like, may be appropriately adjusted, such that contact resistance is reduced. The first electrode structure 21A including the conductive via 21a and the second electrode structure 23A including the second electrode layer 23a may be formed to be in direct contact with surfaces of the first and second conductive semiconductor layers, respectively. Alternatively, the contact regions may be made of a material that is able to form ohmic-contact. Namely, the contact regions may be made of a different material 23a′ from that of other regions.

For an electrical connection with the first conductive semiconductor layer 21, the conductive via 21a may be formed on the first conductive semiconductor layer 21 exposed by etching at least portions of the first conductive semiconductor layer 21, the active layer 22 and the second conductive semiconductor layer 23. Since the conductive via 21a is required to be electrically separated from the active layer 22 and the second conductive semiconductor layer 23, an insulator 30 is formed between the conductive via 21a and the active layer 22 and the second conductive semiconductor layer 23. Any material having electrical insulation properties may be employed as the insulator 30, but a material that absorbs light as minimally as possible is desirous, so, silicon oxide or silicon nitride such as SiO₂, SiOₓN_{y}, SiₓN_{y}, or the like, may be used.

The second electrode structure 23A, electrically connected to the second conductive semiconductor layer 23, may be formed on an upper surface of the second conductive semiconductor layer 23 and may receive an electrical signal through the second electrode pad 23b from the outside. Since the first and second electrode structures 21A and 23A should be electrically separated, the space between the first electrode structure 21A including the conductive via 21a and the second electrode structure 23A may be filled with the insulator 30 within the light emitting structure 20 as shown in FIGS. 1 and 2.

Meanwhile, although not shown, a conductive contact layer (not shown) for ohmic-contact may be further provided between the conductive via 21a and the first conductive semiconductor layer 21. The conductive contact layer may include a material such as Ag, Ni, Al, Rh, Pd, Ir, Ru, Mg, Zn, Pt, Au, or the like, or may have a structure including two or more layers of materials such as Ni/Ag, Zn/Ag, Ni/Al, Zn/Al, Pd/Ag, Pd/Al, Ir/Ag, Ir/Au, Pt/Ag, Pt/Al, Ni/Ag/Pt, or the like.

The first and second electrode pads 21b and 23b may be formed on regions of the conductive via 21a and the second electrode layer 23a which extend from the first and second conductive semiconductor layers 21 and 23 and are exposed from the surface of the light emitting structure 20. The first and second electrode pads 21b and 23b are provided as regions to be electrically connected to a lead frame or an external electrode, and to this end, the first and second electrode pads 21b and 23b may be made of a metallic material having electrical conductivity. With reference to FIG. 3, the first electrode pad 21b may be formed to be in contact with a plurality of conductive vias 21a, electrically connected to the first conductive layer 21 and exposed to the outside, and the second electrode structure 23A connected to the second conductive semiconductor layer 23 may include the second electrode pad 23b. In the present embodiment, the first electrode structure 21A includes a plurality of conductive vias 21a, and the first electrode pad 21b is illustrated to be larger than the second electrode pad 23b, but the present invention is not limited thereto and, as mentioned above, the number, size, shape and pitch of the conductive vias 21a and the size, shape, and the like, of the first and second electrode pads 21b and 23b may be variably modified as necessary.

In the present embodiment, since the light emitting structure 20 is formed on the first main plane of the light-transmissive substrate 10 having a prominence and depression structure on at least one of the first and second main planes, a high quality nitride semiconductor light emitting device having a reduced dislocation defect can be provided. Also, since the light diffusion effect on the interface between the light emitting structure 20 and the light-transmissive substrate 10 is increased, external light extraction efficiency can be enhanced. In addition, since the light emission area is increased by simplifying the electrode structure, luminance of the light emitting device can be remarkably increased.

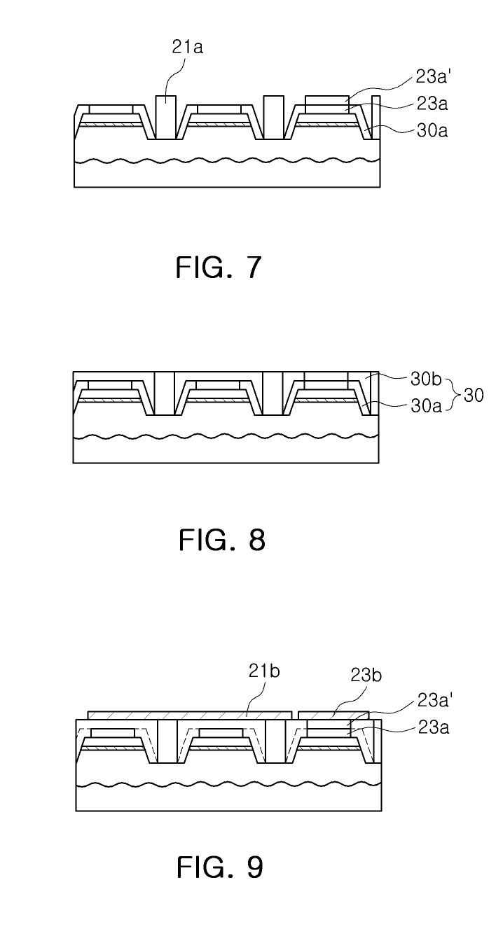

FIGS. 4 through 10 are views sequentially showing a method for fabricating a semiconductor light emitting device according to an embodiment of the present invention. First, as shown in FIG. 4, the light emitting structure 20, including the first conductive semiconductor layer 21, the active layer 22, and the second conductive semiconductor layer 23, is formed on the first main plane of the light-transmissive substrate 10 having prominences and depressions formed on at least one of the first and second main planes thereof. As described above, as the light-transmissive substrate 10, a substrate made of a material such as SiC, MgAl₂O₄, MgO, LiAlO₂, LiGaO₂, GaN, or the like, may be used. In order to form prominences and depressions on an upper surface of the light-transmissive substrate 10, a photoresist layer (not shown) is formed on the light-transmissive substrate 10, light is irradiated to the photoresist layer to form a pattern, and then, a dry or wet etching process is performed to form prominences and depressions such that they correspond to the pattern.

In FIG. 4, it is illustrated that prominences and depressions are directly formed on the surface of the light-transmissive substrate 10, but alternatively, as mentioned above, a prominence and depression structure layer may be formed by using a heterogeneous material which is different from that of the light-transmissive substrate 10. Namely, a prominence and depression structure layer may be formed by using a transparent insulator such as SiO₂, SiNₓ, Al₂O₃, HfO, TiO₂, ZrO, or a transparent conductor formed of ZnO or a transparent conductive oxide (TCOs) such as In oxide containing additives (Mg, Ag, Zn, Sc, Hf, Zr, Te, Se, Ta, W, Nb, Cu, Si, Ni, Co, Mo, Cr). In performing a dry etching process to form prominences and depressions, an etching gas, for example, a fluorine-based etching gas such as CF₄, SF₆, or the like, a chlorine-based etching gas such as Cl₂, BCl₃, or the like, an argon (Ar)-based etching gas, or the like, may be used, but the present invention is not limited thereto and various other known etching gases may also be used.

In growing the first conductive semiconductor layer 21 from the light-transmissive substrate 10 with the prominence and depression structure formed thereon, the first conductive semiconductor layer 21 is grown from the sides of convex portions of the prominence and depression structure. Thus, a dislocation defect caused by the difference in lattice constants between the light-transmissive substrate 10 and the first conductive semiconductor layer 21 is bent to the lateral side according to the lateral growth of the first conductive semiconductor layer 21, rather than propagating upwardly. Thus, within the first grown conductive semiconductor layer 21, the dislocation density in a direction parallel to the main plane of the light-transmissive substrate 10 is very low, thus fabricating a high quality nitride semiconductor light emitting device.

As shown in FIG. 5, portions of the second conductive semiconductor layer 23, the active layer, and the first conductive semiconductor layer 21 may be etched to expose at least a portion of the first conductive semiconductor layer 21. The surface portions of the first conductive semiconductor layer 21 exposed through the etching process are regions in which the conductive vias 21 are formed to be formed, and in a manner similar to that of the process of forming prominences and depressions on the light-transmissive substrate, regions, other than the regions in which the conductive vias 21a are to be formed, are masked, and then, wet or dry etching may be performed to form etched regions in the form of a hole.

Next, as shown in FIG. 6, an insulating layer 30a may be formed to cover the surface of the light emitting structure 20. The insulating layer 30a serves to electrically separate the conductive vias 21a to be formed later, the active layer 22, and the second conductive semiconductor layer 23. The insulating layer 30a may be made of silicon oxide or silicon nitride such as SiO₂, SiOₓN_{y}, SiₓN_{y}, or may be formed to have a thickness of about 6000 Å by using a deposition process such as plasma enhanced chemical vapor deposition (PECVD), or the like.

Then, as shown in FIG. 7, the insulating layer 30a formed on partial regions of the surface of the second conductive semiconductor layer 22 and the first conductive semiconductor layer 21 is removed to expose the first conductive semiconductor layer 21 and the second conductive semiconductor layer 22, and the first electrode structure 21A, including the conductive via 21a and the second electrode structure 23A including the second electrode layer 23a, are formed on the exposed first conductive semiconductor layer 21 and the second conductive semiconductor layer 22, respectively. In the present embodiment, it is illustrated that a plurality of conductive vias 21a are formed, but the number, shape, pitch, and the like, of the conductive vias 21 may be appropriately modified. The first and second electrode structures 21A and 23A serve as electricity application units of the first and second conductive semiconductor layers 21 and 23, so these elements may be formed with a metallic material having excellent electrical conductivity. In detail, the conducive via 21a may have a structure in which Al/Ti/Pt/Ti are sequentially stacked, and the second electrode structure 23A may be configured by sequentially stacking Ag/Ni/Ti/TiN. However, these are merely examples and materials constituting the first and second electrode structures 21A and 23A, or the like, may be appropriately selected from among known metals. Meanwhile, at a region where the second electrode pad (not shown) is to be formed to be connected to the second conductive semiconductor layer 23, the second electrode layer 23a may be adjusted to have a height equal to that of the conductive via 21a, and the second electrode layer 23a may be in contact with the second electrode pad (not shown) by using the same metal as that of the second conductive via 23a or the different metal 23a′.

Thereafter, as shown in FIG. 8, the interior of the light emitting structure 20 may be filled with an insulator 30b in order to electrically separate the first electrode structure 21A including the conductive via 21a and the active layer 22, and the second conductive semiconductor layer 23, and the second electrode structure 23A including the second electrode layer 23a. In this case, at least a portion of the conductive via 21a may be exposed from insulator 30a. Here, the insulator 30b may be made of the same material as that of the insulator 30a formed to cover the surface of the light emitting structure 20 in a previous stage (illustrated in FIG. 6), but the present invention is not limited thereto.

Then, as shown in FIG. 9, the first and second electrode pads 21b and 23b may be formed to be connected to the conductive via 21a and the second electrode layer 23a exposed from the insulators 30a and 30b, respectively. In the present embodiment, the first and second electrode pads 21b and 23b applying an electrical signal to the first and second conductive semiconductor layers 21 and 23 may be formed to be coplanar, and accordingly, since the plane on which the growth light-transmissive substrate 10 is positioned is provided as a light extraction face, a light emission area can be maximized. In detail, the first and second electrode pads 21b and 23b may be made of a material including any one among Au, Ni, Al, Cu, W, Si, Se, and GaAs.

Subsequently, as shown in FIG. 10, a prominence and depression structure may be formed on the second main plane of the light-transmissive substrate 10, i.e., on the face opposed to the first main plane on which the light emitting structure 20 is formed. The prominence and depression structure may be formed to have a regular or irregular period, and the size, shape, pitch, and the like thereof may be variably modified as necessary. Also, in a similar manner to that of the process of forming the prominences and depressions on the first main plane of the light-transmissive substrate 10, a mask pattern may be formed by using photoresist, and then, the prominence and depression structure may be formed on the second main plane of the light-transmissive substrate 10 through wet or dry etching. Alternatively, prominences and depressions may be formed on the surface by using an etching solution without a mask pattern. In the present embodiment, since the prominence and depression structure is formed on the second main plane of the light-transmissive substrate 10, i.e., the light extraction face of the semiconductor light emitting device, the ratio of total reflection at the interface between the light-transmissive substrate 10 and air can be reduced, thus enhancing external light extraction efficiency. Also, since a process for removing the growth substrate is not required, the process can be simplified and defects otherwise generated in the process of removing the growth substrate can be avoided.

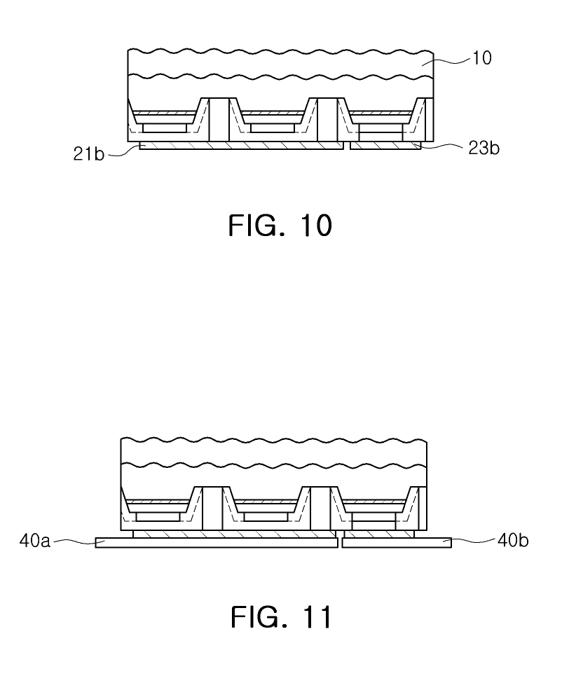

FIG. 11 is a view schematically showing a mounting form of a semiconductor light emitting device package according to an embodiment of the present invention. With reference to FIG. 11, a light emitting device package according to the present embodiment includes first and second terminal units 40a and 40b, and a semiconductor light emitting device package is electrically connected to the first and second terminal units 40a and 40b. In this case, the semiconductor light emitting device has the same structure as that of FIG. 1, in which the first conductive semiconductor layer 21 may be connected to the first terminal unit 40a through the first electrode pad 21b and the second conductive semiconductor layer 23 may be connected to the second terminal unit 40b by the second electrode 23b. In the present embodiment, light can be uniformly emitted from the entire regions of the semiconductor light emitting device, and since the first electrode pad 21b is connected to the first conductive semiconductor layer 21 through the first conductive via 21a, a region to be etched for forming an electrode can be reduced, enhancing light extraction efficiency, and since a current is injected through a plurality of first and second conductive vias 21a and 23a, a current distribution effect can be increased to uniformly emit light.

As set forth above, according to embodiments of the invention, a high quality semiconductor light emitting device having reduced dislocation defects and enhanced external light extraction efficiency can be provided.

Also, in the semiconductor light emitting device, the light emission area can be increased by simplifying the electrode structure, and since current distribution efficiency is increased therein, light can be uniformly emitted.

In addition, since the structure and fabrication process of the semiconductor light emitting device are simplified, the efficiency of semiconductor light emitting device fabrication process can be enhanced, and a defect generated in the process of removing a growth substrate can be eliminated.

Moreover, a method for fabricating a high quality semiconductor light emitting device having enhanced external light extraction efficiency and emitting uniform light can be provided.

While the present invention has been shown and described in connection with the embodiments, it will be apparent to those skilled in the art that modifications and variations can be made without departing from the spirit and scope of the invention as defined by the appended claims.

What is claimed is:

1. A semiconductor light emitting device comprising:
a light-transmissive substrate including opposed first and second main planes and having prominences and depressions formed on at least one of the first and second main planes thereof;
a light emitting structure formed on the first main plane of the substrate and including a first conductive semiconductor layer, an active layer, and a second conductive layer sequentially formed in a direction away from the first main plane;
a first electrode structure disposed on a side of the substrate opposed to the light emitting structure and including a conductive via connected to the first conductive semiconductor layer through the second conductive semiconductor layer and the active layer;
a second electrode structure disposed on the side of the substrate opposed to the light emitting structure and connected to the second conductive semiconductor layer; and
an insulator electrically separating the first electrode structure from the second conductive semiconductor layer, the active layer, and the second electrode structure.

2. The semiconductor light emitting device of claim 1, wherein a plurality of conductive vias are provided, and the insulator is formed to fill the regions between the plurality of conductive vias and the light emitting structure.

3. The semiconductor light emitting device of claim 1, wherein the first and second electrode structures are formed to face the same direction.

4. The semiconductor light emitting device of claim 1, further comprising a first electrode pad connected to the conductive vias.

5. The semiconductor light emitting device of claim 1, further comprising a second electrode pad formed on an upper surface of the second conductive semiconductor layer.

6. The semiconductor light emitting device of claim 1, wherein the light-transmissive substrate is an insulating substrate.

7. The semiconductor light emitting device of claim 1, wherein the prominences and depressions formed on the light-transmissive substrate include a convex portion with a sloped lateral face.

8. The semiconductor light emitting device of claim 1, wherein the first and second conductive semiconductor layers are n-type and p-type semiconductor layers, respectively.

9. A method for fabricating a semiconductor light emitting device, the method comprising:
preparing a light-transmissive substrate including opposed first and second main planes and having prominences and depressions formed on at least one of the first and second main planes thereof;
forming a light emitting structure in which a first conductive semiconductor layer, an active layer, and a second conductive semiconductor layer are sequentially stacked on a prominence and depression surface of the substrate;
etching portions of the second conductive semiconductor layer and the active layer to expose at least a portion of the first conductive semiconductor layer;
forming a first electrode structure including conductive vias electrically connected to the first conductive semiconductor layer on the etched region;
forming a second electrode structure electrically connected to the second conductive semiconductor layer on the second conductive semiconductor layer; and
forming an insulator to electrically separate the first electrode structure from the second conductive semiconductor layer, the active layer, and the second electrode structure.

10. The method of claim 9, wherein the conductive vias are formed to penetrate the second conductive semiconductor layer and the active layer.

11. The method of claim 9, wherein, in the forming of the insulator, the insulator is formed to fill the etched regions formed between the conductive vias and the light emitting structure.

12. The method of claim 9, wherein the prominences and depressions formed on at least one of the first and second main planes include a convex portion with a sloped lateral face, and at least a portion of the first conductive semiconductor layer is grown from the lateral face of the convex portion.

13. The method of claim 9, further comprising forming an insulator to cover the surface of the light emitting structure, before forming the conductive vias.
